(19) United States
(12) Patent Application Publication
(10) Pub. No.: US 2010/0121589 A1
(43) Pub. Date: May 13, 2010

(54) APPARATUS AND METHOD FOR IMPLEMENTING APPLICATION USING SOLAR BATTERY CHARGING OF PORTABLE TERMINAL

(75) Inventor: Bo-Ram NAMGOONG, Seoul (KR)

Correspondence Address: Jefferson IP Law, LLP, 1130 Connecticut Ave., NW, Suite 420, Washington, DC, 20036, US

(73) Assignee: SAMSUNG ELECTRONICS CO. LTD., Suwon-si (KR)

(21) Appl. No.: 12/570,438

(22) Filed: Sep. 30, 2009

(30) Foreign Application Priority Data
Nov. 12, 2008 (KR) 10-2008-0111951

(51) Int. Cl. G01R 31/36; H01M 10/46

(52) U.S. Cl. 702/63; 320/101

(57) ABSTRACT

An apparatus and method for implementing an application using solar battery charging of a portable terminal are provided. The method includes determining the accumulated charging time of the solar battery, extracting an image corresponding to the determined accumulated charging time of the solar battery from a storage unit, and displaying the extracted image on a display unit. Accordingly, a user may be entertained by plant growing at the same time of charging the solar battery.

### PRIORITY

This application claims the benefit under 35 U.S.C. §119(a) of a Korean patent application filed in the Korean Intellectual Property Office on Nov. 12, 2009 and assigned Serial No. 10-2008-0111951, the entire disclosure of which is hereby incorporated by reference.

### BACKGROUND OF THE INVENTION

1. Field of the Invention

The present invention relates to an apparatus and method for implementing an application using an accumulated charging time (or charging amount) of a solar battery of a portable terminal. More particularly, the present invention relates to an apparatus and method for determining an accumulated charging time (or charging amount) of a solar battery of a portable terminal and for utilizing the determined accumulated charging time (or charging amount) of the solar battery to play games such as growing a pet plant or the like.

2. Description of the Related Art

Conventional portable terminals are equipped with batteries to receive power voltage from the batteries. In general, when a battery is discharged to a certain threshold, the battery may not be used or has to be recharged. Therefore, a user occasionally replaces the battery or recharges the battery by using a battery charger.

The battery charger used to charge the battery of the portable terminal charges the battery in such a manner that Alternating Current (AC) power is down-converted to Direct Current (DC) and then desired voltage is supplied to the battery. Since the battery is charged by using a separated battery charger in a place where the AC power is supplied, a problem arises in that a place capable of charging the battery is limited.

To solve such a problem, research has been conducted for using solar energy to charge the battery. That is, a method for providing a portable terminal with a built-in solar battery has been researched. The solar battery operates by converting light energy provided from the sun into electrical energy. As such, when the battery is charged using the solar energy, not only the portable terminal may be supplied with sufficient power voltage anytime anywhere, but also energy may be saved.

To achieve energy saving, there may be a method for charging the solar battery while the portable terminal is used by a user not to use a simple function but to enjoy entertainment. Accordingly, there is a need for a method of promoting the use of the solar battery so that the user directly charges the solar battery.

### SUMMARY OF THE INVENTION

An aspect of the present invention is to address at least the above-mentioned problems and/or disadvantages and to provide at least the advantages described below. Accordingly, an aspect of the present invention is to provide an apparatus and method for implementing an application that may be interactive with a user by using an accumulated charging time (or charging amount) of a solar battery of a portable terminal.

Another aspect of the present invention is to provide an apparatus and method for determining an accumulated charging time (or charging amount) of a solar battery of a portable terminal and for utilizing the determined accumulated charging time (or charging amount) of the solar battery to play games such as growing a pet plant or the like.

In accordance with an aspect of the present invention, a method for indicating an accumulated charging time of a solar battery of a portable terminal is provided. The method includes determining an accumulated charging time of a solar battery, extracting an image corresponding to the determined accumulated charging time of the solar battery from a storage unit, and displaying the extracted image on a display unit.

In accordance with another aspect of the present invention, an apparatus for indicating an accumulated charging time of a solar battery of a portable terminal is provided. The apparatus includes a determiner for determining an accumulated charging time of a solar battery, and an application unit for extracting an image corresponding to the determined accumulated charging time of the solar battery from a storage unit and for displaying the extracted image on a display unit.

Other aspects, advantages, and salient features of the invention will become apparent to those skilled in the art from the following detailed description, which, taken in conjunction with the annexed drawings, discloses exemplary embodiments of the invention.

### BRIEF DESCRIPTION OF THE DRAWINGS

The above and other aspects, features, and advantages of certain exemplary embodiments of the present invention will be more apparent from the following detailed description taken in conjunction with the accompanying drawings, in which:

FIG. 1 is a block diagram illustrating a structure of a portable terminal according to an exemplary embodiment of the present invention;

FIG. 2 is a flowchart illustrating a method for implementing an application that may be interactive with a user by using an accumulated charging time of a solar battery of a portable terminal according to an exemplary embodiment of the present invention; and

FIG. 3 illustrates an example of a method for displaying an image corresponding to an accumulated charging time of a solar battery of a portable terminal according to an exemplary embodiment of the present invention.

Throughout the drawings, like reference numerals will be understood to refer to like parts, components and structures.

### DETAILED DESCRIPTION OF EXEMPLARY EMBODIMENTS

The following description with reference to the accompanying drawings is provided to assist in a comprehensive understanding of exemplary embodiments of the present invention as defined by the claims and their equivalents. It includes various specific details to assist in that understanding but these are to be regarded as merely exemplary. Accordingly, those of ordinary skill in the art will recognize that various changes and modifications of the embodiments described herein may be made without departing from the scope and spirit of the invention. Also, descriptions of well-known functions and constructions are omitted for clarity and conciseness.

The terms and words used in the following description and claims are not limited to the bibliographical meanings, but, are merely used by the inventor to enable a clear and consistent understanding of the invention. Accordingly, it should be apparent to those skilled in the art that the following description of exemplary embodiments of the present invention are provided for illustration purpose only and not for the purpose of limiting the invention as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

By the term “substantially” it is meant that the recited characteristic, parameter, or value need not be achieved exactly, but that deviations or variations, including for example, tolerances, measurement error, measurement accuracy limitations and other factors known to those of skill in the art, may occur in amounts that do not preclude the effect the characteristic was intended to provide.

Hereinafter, an apparatus and method for implementing an application that may be interactive with a user by using an accumulated charging time of a solar battery of a portable terminal will be described. Although exemplary embodiments of the present invention describe the accumulated charging time for charging the solar battery for example, the accumulated charging time may be replaced with an accumulated charging amount.

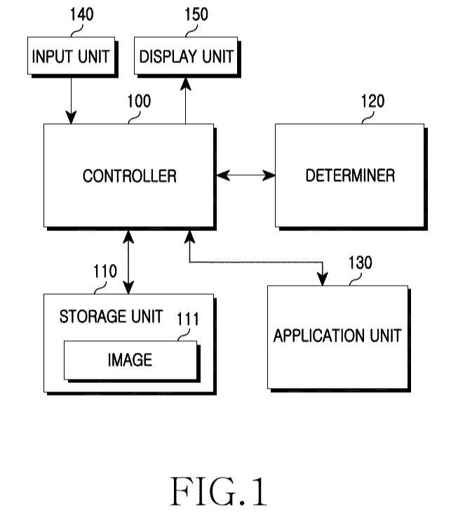

FIG. 1 is a block diagram illustrating a structure of a portable terminal according to an exemplary embodiment of the present invention.

Referring to FIG. 1, the portable terminal includes a controller 100, a storage unit 110, a determiner 120 for determining an accumulated charging time of a solar battery, an application unit 130, an input unit 140, and a display unit 150.

The controller 100 controls and processes overall operations of the portable terminal. In particular, the controller 100 performs controlling and processing for implementing an application that may be interactive with a user by using the accumulated charging time of the solar battery.

The storage unit 110 stores a variety of information and a program required for the overall operations of the portable terminal. In particular, the storage unit 110 stores a table of an image 111 for each accumulated charging time.

The determiner 120 determines the accumulated charging time of the solar battery.

The application unit 130 extracts an image corresponding to the determined accumulated charging time of the solar battery from the storage unit 110. Thus, the application unit 130 uses the extracted image to play games such as growing a pet plant or the like.

The input unit 140 has a plurality of functional keys and provides the controller 100 with data corresponding to a key pressed by the user. The display unit 150 displays state information, numeric characters, alphabetic characters, or the like which are generated in the operation of the portable terminal.

Although not shown in FIG. 1, instead of the determiner 120 for determining the accumulated charging time of the solar battery, a determiner for determining an accumulated charging amount of the solar battery may be implemented to determine the accumulated charging amount of the solar battery.

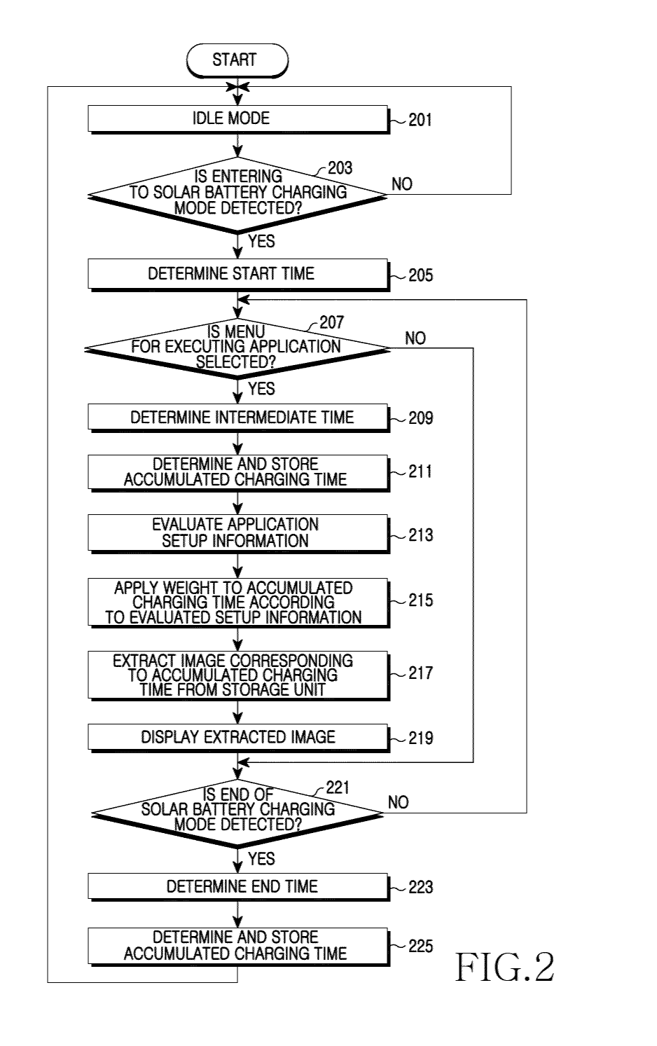

FIG. 2 is a flowchart illustrating a method for implementing an application that may be interactive with a user by using an accumulated charging time of a solar battery of a portable terminal according to an exemplary embodiment of the present invention.

Referring to FIG. 2, the portable terminal operates in an idle mode in step 201. In step 203, the portable terminal determines whether entering into a solar battery charging mode is detected. A battery is charged in the solar battery charging mode by converting light energy provided from the sun into electrical energy. In this case, when current initially flows to a charging Integrated Circuit (IC), the portable terminal may detect the entering into the solar battery charging mode. If the entering into the solar battery charging mode is not detected, returning to step 201, the subsequent steps are repeated. Otherwise, if the entering into the solar battery charging mode is detected, the portable terminal determines a time at which the solar battery charging mode starts in step 205, that is, a time at which current starts to initially flow to the charging IC.

In step 207, the portable terminal determines whether a menu for executing an application using the solar battery is selected corresponding to key manipulation of the user. If it is determined that the menu for executing the application is not selected, the procedure proceeds to step 221. Otherwise, if it is determined that the menu for executing the application is selected, the portable terminal determines a time elapsed from the start time of the solar battery charging mode in step 209, that is, determines an intermediate time.

In step 211, the portable terminal determines an accumulated charging time by using the determined start time and intermediate time of the solar battery charging mode, and stores the determined accumulated charging time. The accumulated charging time may be determined by determining a difference value between the intermediate time and the start time and by summing the difference value and a previously determined and stored accumulated charging time.

In step 213, the portable terminal evaluates information which is pre-set by the user for the application. For example, an application using the solar battery may be a game such as growing a pet plant or the like. In this case, a setup menu may include a ‘plant type’ depending on a level of difficulty, and may include an option required for plant growing, such as ‘watering’, ‘fertilizing’, ‘insecticiding’, etc. When the setup menu is displayed on the display unit corresponding to user's key manipulation, the user may select the ‘plant type’ and the option such as ‘watering’, ‘fertilizing’, ‘insecticiding’, etc., and the portable terminal may store the selection result as setup information. That is, the application setup information may be information indicating whether at least one option required for plant growing is set among ‘watering’, ‘fertilizing’, and ‘insecticiding’. Each option required for plant growing may promote a growing rate of the plant corresponding to an accumulated charging time of the solar battery during a preset time interval, and this may be realized by assigning a weight to each option and by applying the weight-applied option to the accumulated charging time. The plant type is various according to the level of difficulty. That is, the plant may be selected from various types of plants, for example, from a plant which is easy to grow to a plant which is difficult to grow (e.g., a plant blooming once in 100 years). In an exemplary implementation, the plant blooming once in 100 years may bloom when a certain condition corresponding to a high level of difficulty is satisfied, instead of actually waiting for 100 years in real life.

In step 215, the portable terminal applies a weight to the determined accumulated charging time corresponding to the evaluated application setup information. That is, if there is a preset option as the application setup information, the weight assigned to the preset option is applied to the accumulated charging time. For example, if ‘t’ denotes the accumulated charging time, ‘a’ denotes a weight of the ‘watering’ option, ‘b’ denotes a weight of the ‘fertilizing’ option, and ‘c’ denotes a weight of the ‘insecticiding’ option, then various formulas such as ‘(a+b+c)*t’ or ‘a*t+b+c’ or ‘t+a+b+c’ may be used to apply the weight of the preset option by the user to the determined accumulated charging time. In case of selecting the ‘insecticiding’ option, an insecticide may be used to deal with insect attacks, and an overall score decreases in this process. This mechanism may also be applied to other cases. In exemplary implementations, too much watering or fertilizing may adversely affect plant growing and may cause abnormal growing. The present invention is not limited to the aforementioned exemplary embodiment, and thus various elements may be applied in various forms.

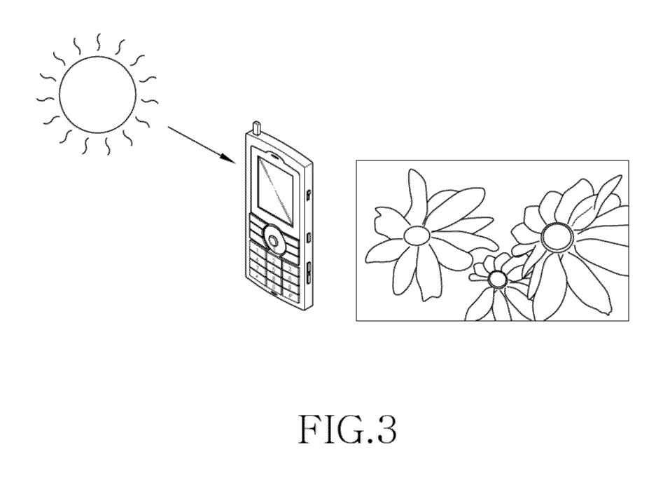

In step 217, the portable terminal extracts an image corresponding to the weight-applied accumulated charging time from the storage unit. In step 219, the portable terminal displays the extracted image to the display unit as shown in FIG. 3. A table of the image for each accumulated charging time is stored in the storage unit 110. For example, a plant growing process may be stored as an image for each accumulated charging time. That is, if the accumulated charging time is as low as a level 1, an image of sprouting may be stored as a corresponding image, and if the accumulated charging time is as high as a level 10, an image of fruiting may be stored as a corresponding image.

Herein, if the accumulated charging time is greater than or equal to a threshold time, point conversion is possible. A point may be used to downlink various types of plants and items required for growing a pet plant (i.e., flowerpots, manures, insecticides, etc.) through a web. For example, if the plant produces a fruit, the fruit may be converted into a point. The point of the fruit may be set differently corresponding to a level of difficulty of plant growing.

In step 221, the portable terminal determines whether the solar battery charging mode ends. In this case, if current does not flow through the charging IC during a specific time interval, the portable terminal may detect the end of the solar battery charging mode. If it is determined that the end of the solar battery charging mode is not detected, returning to step 207, the subsequent steps are repeated. Otherwise, if it is determined that the end of the solar battery charging mode is detected, the portable terminal determines a time at which the solar battery charging mode ends in step 223, that is, determines a time at which current starts to not flow through the charging IC for the specific time duration.

In step 225, the portable terminal determines an accumulated charging time by using the determined end time of the solar battery charging mode and a time determined immediately before the end time, and stores the determined accumulated charging time. The time determined immediately before the end time may be the intermediate time if the intermediate time is determined after determining the start time, and may be the start time if the intermediate time is not determined after determining the start time. The accumulated charging time may be determined by summing a difference value between the end time and the time determined immediately before the end time and the previously determined and stored accumulated charging time.

Thereafter, returning to step 201, the subsequent steps are repeated.

Exemplary embodiments of the present invention may apply to an educational application capable of teaching a place of growing, a temperature, a climate, a growth method, etc. Further, exemplary embodiments of the present invention may also apply to an idle screen or may be used in cooperation with icons of various programs. The idle screen may display a flower which has been grown by the application. Alternatively, independently from a growing result obtained by the application, the idle screen may display a degree of flowering by simply determining or measuring a charging time (or charging amount) of a solar battery.

In addition, exemplary embodiments of the present invention may be used in cooperation with a community service among users, a donation activity of donating a part of a user's current balance for environment protection, and so on. A plant grown by the user may be displayed on a website by using an activity of making a garden in a form of a mini-homepage.

According to exemplary embodiments of the present invention, a portable terminal determines an accumulated charging time (or charging amount) of a solar battery and utilizes the determined charging time (or charging amount) of the solar battery to play games such as growing a pet plant. Therefore, a user may be entertained by plant growing at the same time of charging the solar battery, thereby promoting the use of the solar battery which may otherwise be an inconvenience due to a charging process. As a result, energy saving may be achieved. In addition, the solar battery may be generalized for mobile purposes, and a web service of the portable terminal may be more frequently used.

Certain aspects of the present invention can also be embodied as computer readable code on a computer readable recording medium. A computer readable recording medium is any data storage device that can store data which can be thereafter read by a computer system. Examples of the computer readable recording medium include Read-Only Memory (ROM), Random-Access Memory (RAM), CD-ROMs, magnetic tapes, floppy disks, optical data storage devices, and carrier waves (such as data transmission through the Internet). The computer readable recording medium can also be distributed over network coupled computer systems so that the computer readable code is stored and executed in a distributed fashion. Also, functional programs, code, and code segments for accomplishing the present invention can be easily construed by programmers skilled in the art to which the present invention pertains.

While the present invention has been shown and described with reference to certain exemplary embodiments thereof, it will be understood by those skilled in the art that various changes in form and details may be made therein without departing from the spirit and scope of the present invention as defined by the appended claims and their equivalents.

What is claimed is:

1. A method for indicating an accumulated charging time of a solar battery of a portable terminal, the method comprising:
determining an accumulated charging time of a solar battery;
extracting an image corresponding to the determined accumulated charging time of the solar battery from a storage unit; and
displaying the extracted image on a display unit.

2. The method of claim 1, wherein the accumulated charging time comprises an accumulated charging amount.

3. The method of claim 1, wherein the determining of the accumulated charging time of the solar battery comprises determining a start time at which entering into a solar battery charging mode is detected.

4. The method of claim 3, wherein the determining of the accumulated charging time of the solar battery comprises:
determining an intermediate time at which at least one of selection of a menu for executing an application is detected and an end time at which a solar battery charging end mode is detected;
determining a difference value between one of the determined intermediate time and the end time and the determined start time; and
summing the determined difference value and a previously determined and stored accumulated charging time of the solar battery.

5. The method of claim 1, wherein the image corresponding to the accumulated charging time of the solar battery comprises an image related to a plant growing process over time.

6. The method of claim 1, further comprising, before the extracting of the image:
evaluating application setup information; and
applying a weight to the accumulated charging time of the solar battery corresponding to the evaluated application setup information,
wherein the extracting of the image comprises a process of extracting the image corresponding to the weight-applied accumulated charging time of the solar battery from the storage unit.

7. The method of claim 6, wherein the application setup information indicates whether at least one of options of ‘watering’, ‘fertilizing’, and ‘insecticiding’ required for plant growing is set, and a weight is assigned for each option.

8. The method of claim 7, wherein the applying of the weight comprises a process in which a weight assigned to a corresponding option is applied to the accumulated charging time of the solar battery when a preset option exists as the application setup information.

9. The method of claim 6, wherein the application setup information comprises information on a pre-selected plant, and the plant is selected variously according to a level of difficulty.

10. The method of claim 1, further comprising:
if the determined accumulated charging time of the solar battery is greater than or equal to a threshold time, converting the accumulated charging time of the solar battery into a point; and
using the converted point when an item is downloaded through a web.

11. The method of claim 1, wherein the displaying of the extracted image on the display unit is a process in which the extracted image is displayed on an idle screen.

12. An apparatus for indicating an accumulated charging time of a solar battery of a portable terminal, the apparatus comprising:
a determiner for determining an accumulated charging time of a solar battery; and
an application unit for extracting an image corresponding to the determined accumulated charging time of the solar battery from a storage unit and for displaying the extracted image on a display unit.

13. The apparatus of claim 12, wherein the accumulated charging time comprises an accumulated charging amount.

14. The apparatus of claim 12, wherein the determiner comprises a first element for determining a start time at which entering into a solar battery charging mode is detected.

15. The apparatus of claim 14, wherein the determiner further comprises:
a second element for determining an intermediate time at which at least one of selection of an application execution menu is detected and an end time at which a solar battery charging end mode is detected,
a third element for determining a difference value between at least one of the determined intermediate time and the end time and the determined start time; and
a forth element for summing the determined difference value and a previously determined and stored accumulated charging time of the solar battery.

16. The apparatus of claim 12, wherein the image corresponding to the accumulated charging time of the solar battery comprises an image related to a plant growing process over time.

17. The apparatus of claim 12, wherein the application unit evaluates application setup information, applies a weight to the accumulated charging time of the solar battery corresponding to the evaluated application setup information, and extracts the image corresponding to the weight-applied accumulated charging time of the solar battery from the storage unit.

18. The apparatus of claim 17, wherein the application setup information indicates whether at least one of options of ‘watering’, ‘fertilizing’, and ‘insecticiding’ required for plant growing is set, and a weight is assigned for each option.

19. The apparatus of claim 18, wherein the application unit applies a weight assigned to a corresponding option to the accumulated charging time of the solar battery when a preset option exists as the application setup information.

20. The apparatus of claim 17, wherein the application setup information comprises information on a pre-selected plant, and the plant is selected variously corresponding to a level of difficulty.

21. The apparatus of claim 12, wherein, if the determined accumulated charting time of the solar battery is greater than or equal to a threshold time, the application unit converts the accumulated charging time of the solar battery into a point, and uses the converted point when an item is downloaded through a web.

22. The apparatus of claim 12, wherein the application unit displays the extracted image on an idle screen.

23. A computer-readable recording medium having recorded thereon a program for a portable terminal, the computer-readable recording medium comprising:
a first code segment, for determining an accumulated charging time of a solar battery;
a second code segment, for extracting an image corresponding to the determined accumulated charging time of the solar battery from a storage unit; and
a third code segment, for displaying the extracted image on a display unit.
